(19) United States
(12) Patent Application Publication
(10) Pub. No.: US 2009/0065053 A1
(43) Pub. Date: Mar. 12, 2009

(54) Photovoltaic device

(76) Inventor: Julian Gulbinski, Jamison, PA (US)

Correspondence Address: GREGORY J. GORE, 70 WEST OAKLAND AVENUE, SUITE 316, DOYLESTOWN, PA, 18901, US

(21) Appl. No.: 12/222,622

(22) Filed: Aug. 13, 2008

Related U.S. Application Data
(60) Provisional application No. 60/957,905, filed on Aug. 24, 2007.

(51) Int. Cl. H01L 31/00

(52) U.S. Cl. 136/256

(57) ABSTRACT

A photovoltaic device employs several major components or features which work together to provide a device that allows for the use of many different photoactive chemicals simultaneously to more efficiently convert solar energy into electrical energy. In the order of sunlight impingement, the components comprise: a physical interruption device, a resolving mechanism and a gap or space between the resolving mechanism and the next component, a chemical composition of photoactive chemicals. An electron capture mechanism includes electrodes which derive the electrical charge from the electron capture mechanism. The last feature is an electronic control mechanism which coordinates the polarity of the electrodes and the movement of the photo interruption device. Polarity reversal and pulsed excitation are key to the operation of the device.

### RELATED APPLICATIONS

The present patent application is related to U.S. Provisional Patent Application Ser. No. 60/957,905 filed Aug. 24, 2007 entitled “Photovoltaic Device,” priority from which is hereby claimed.

### FIELD OF THE INVENTION

The present invention relates to devices for converting sunlight into electricity. More specifically, it relates to a solar device in which the homogeneous sunlight is resolved into different wavelengths and directed toward specialized chemicals most responsive to a resolved wavelength.

### BACKGROUND OF THE INVENTION

There are many different types of photoactive chemicals, and some of them are very efficient at converting specific regions of solar energy into chemical energy. There are two types of photoactive chemicals: the reversible and the non-reversible. The reversible photoactive chemicals can be further subdivided into several major classifications: chemicals which undergo photo-isomerization; photo-rearrangement; photo-oxidation; and free-radical formation. Many of these chemicals can be found in nature and are responsible for thousands of chemical and biochemical processes such as vision, photosynthesis, phototaxis, vitamin production and the process of tanning. All of these processes are initiated by some type of photoactive chemical which converts a portion of sunlight into chemical energy, which then usually triggers some other bio-chemical process resulting in a bio-chemical or physical change.

One example of a photoactive chemical which undergoes photo-isomerization is retinal, generically referred to as vitamin A. Retinal is the primary chemical responsible for the conversion of visible light energy into chemical energy in the eye. Retinal starts as cis-retinal and through the photo-absorptive process it converts the solar energy into chemical energy through photo-isomerization, resulting in trans-retinal. Once it has been converted into trans-retinal, the trans-retinal triggers a biochemical cascade that results in visual impulses. Retinal, like many of the reversible photoactive chemicals, has the ability convert from one form, “cis-retinal,” to another form, “trans-retinal,” over and over again. Many photoactive chemicals can undergo the photo isomerization process thousands, millions or billions of times each second. Each of these chemicals has a different conversion process whereby photo-energy is converted into chemical energies, including but not limited to photo-isomerizations, photo-rearrangements, and free-radical formation. These photoactive effects result in chemicals at higher energy states or chemicals with highly energized electrons, i.e. Pi bonds elevated to Pi* bonds. Finally, and most importantly, by the nature of many photo-sensitive chemicals their reaction rates to light energy are very fast. Some photosensitive chemicals can react to the light energy in one one-billionth of a second or faster. This speed and reversibility makes these chemicals ideal for use in a variety of photovoltaic devices. Other classes of chemicals are photo-rearrangement chemicals which change their shape and can create loose electrons either in the form of a charge or a free-radical.

Some reversible photoactive chemicals can be used in the ultraviolet (UV) region, where the associated energies for each wavelength are higher. These photo-rearrangements occur very fast and are reversible, making them good candidates in photovoltaic devices. However, some of these chemicals require a stimulus to return to their ground state. One good example of a photo-rearrangement chemical is norbornadiene, which photo-converts to a quadracyclane when exposed to sunlight. The wavelength regions are in the ultraviolet region but are dependent on the specific derivatives of the norbornadiene functional groups. This photo-selectivity is an important quality of norbornadiene.

A required chemical aspect of photovoltaic systems is a charge transfer mechanism or electron capture mechanism. The electron capture mechanism is any conductive or a semi-conductive matrix that will transfer the chemical energy from the photoactive chemicals into the charge transfer matrix. The specific nature of the charge transfer matrix enables the efficient transfer of charge between the photosensitive chemicals and the charge transfer matrix. There are numerous types of conductive and/or semi-conductive charge transport matrixes, including but not limited to metal films, conductive graphites, various forms of silicone and many types of conductive and semi-conductive polymers. Because photoactive chemicals generate a small charge very quickly, it is imperative that the charge transfer mechanism be chemically integrated with the photoactive chemicals in order to efficiently remove that charge from the photoactive chemical to the charge transfer matrix. By covalently linking the photoactive chemicals to a charge transfer mechanism via the chemical conjugation, an efficient transfer of charge can occur. Many photoactive chemicals have specific regions or wavelength ranges in which they will convert photo energy into chemical energy. Some chemicals absorb ultraviolet light, others absorb different wavelengths of visible light, and still others-absorb infrared light.

The concepts expressed above are known to the prior art, however they have not been adequately utilized together to maximize the efficiency of photovoltaic devices which convert sunlight into electricity. Prior art devices are relatively inefficient, requiring a large area of sunlight exposure in intense sunlight to be practical.

### SUMMARY OF THE INVENTION

In order to overcome the deficiencies in the prior art, the present invention has been devised. As described below, the invention employs at least six major components or features which work together to provide a device that allows for the use of many different photoactive chemicals simultaneously to more efficiently convert solar energy into electrical energy. The following are general descriptions of these components, presented in the sequence of sunlight striking a device, and converted into electrical energy.

The first component is a component which causes a physical interruption of the solar energy's passage to the photoactive chemicals. Some photoactive chemicals become charged when exposed to solar energy but need to be protected from solar energy in order to give up their charge and return to the uncharged state. By briefly interrupting the exposure of the photoactive chemicals to direct sunlight, the photoactive chemicals will be allowed to return to a ground, or uncharged, state. Such a component may be, for example, an apertured or rotating disc. This first component is optional, depending on the specific requirements of the rest of the device.

The next component is a resolving mechanism which breaks the homogeneous sunlight into the constituent wavelength regions, from the infrared region through the visible range to the ultraviolet region. This resolving mechanism enables the different wavelength regions of light to be targeted onto those individual photoactive chemicals which can more efficiently utilize that specific wavelength region of solar energy. The resolving mechanism may also provide a transparent physical barrier to protect the photoactive chemicals. This component may be separated from the light interrupter by an ambient spacing.

The next feature is an environmental gap, or a controlled environment, the physical space between the resolving mechanism and the photoactive chemicals. This gap will allow for flexibility in creating the best environmental conditions for efficiency and/or stability of the photoactive chemical mixtures. This gap may be a sealed volume containing an environment different from the ambient environment, such as a vacuum, or one containing an inert gas, or some other non-ambient environment.

The fourth element, and a key feature of the invention, are the different photoactive chemicals which may be used concurrently, each receiving a selected range of wavelength of the incident sunlight. Certain photoactive chemicals are very efficient at converting specific wavelengths of solar energy into chemical energy under the correct environmental conditions. The potential list of photoactive chemicals is extremely broad and includes any chemical which absorbs light and converts that energy into chemical energy. The photoactive chemicals utilized in the present invention are those photoactive chemicals which undergo reversible photoactivity like retinal and many of the derivations.

A fifth component is the charge transfer, or electron capture, mechanism. This mechanism is any conductive or semi-conductive material which can be derived chemically, or linked to the desired photoactive chemicals. By chemically or electrochemically deriving the electron capture mechanism with the photoactive chemicals, this mechanism becomes chemically integrated with the photoactive chemicals, making an efficient transfer of chemical energy from the photoactive chemicals into electrical charge of the electron capture mechanism.

The next and sixth feature is the electrodes. Due to the nature of certain photoactive chemicals and their integration with the electron capture mechanism, the electrodes must have the ability to reverse the polarization and carry current in both directions. This reverse polarization may allow the photoactive chemicals to continuously cycle between charged and uncharged states via the electron capture mechanism. It may be necessary to reverse the polarity.

The seventh and last feature in the process is the electronic control mechanism. This mechanism is an external electronic system which coordinates the polarity of the electrodes and the movement of the photo interruption device. The coordination of the change in polarity will be driven by the output of the device at an optimum rate of cycling to maximize output. Depending on the light intensity, as the light gets more intense the cycle may be sped up, thus generating more current per unit of time. If the solar energy is less intense, a slower cycle rate will actually generate more current per unit of time than a faster cycle rate because the photoactive chemicals will not be able to achieve their maximum charge potential at the faster cycle rates. By slowing down the cycle rates, the current per unit time may increase. When the intensity of solar energy is below a certain threshold, the photoactive chemicals need more time to achieve their maximum charge potential. Therefore, at low levels of solar intensity a slower cycle rate will actually generate more current per unit of time because the photoactive chemicals will have enough time to achieve their maximum charge potential. As the intensity of the solar energy increases, the cycle rates will increase because the photoactive chemicals will achieve their maximum potential more quickly.

There are two key chemical aspects which make this new device different from most other photovoltaic systems and which enable it to offer a greater potential for efficiency. The first is the concurrent utilization of a variety of different photoactive chemicals, each responding to a different wavelength or region of light. The second is an electron capture mechanism that provides a uniform platform for which all photoactive chemicals can be integrated to greater integration with the photoactive chemicals. In general, this device employs highly efficient photosensitive materials and chemically integrates them into a charge transport or electron capture mechanism. In addition to the photosensitive chemicals (or active sites) and the charge transport mechanism, this device optimizes the photosensitive characteristics of many different photosensitive chemicals while at the same time minimizing certain limitations of these photosensitive chemicals.

The present invention also utilizes a different type of electrical circuitry than the traditional photovoltaic devices. Most photovoltaic devices are designed on a sandwich configuration, which separates an electron acceptor and an electron donator. The present invention integrates the photoactive materials and the charge transport mechanism, creating a more efficient transfer of chemical energy from the photoactive chemicals into the charge transport matrix. Because of the specific properties of the photoactive chemicals, the charge transport mechanism is required to carry charge away from the photoactive chemicals and may also be required to carry some portion of the charge back to the photoactive chemicals in order for the photoactive chemicals to return to a ground state, or to reset the photoactive chemical to a non-elevated state. However, once the chemicals have reacted to the photo-energy, they are effectively finished and can do no more work. Only once the photoactive chemical has been drained of its charge, or “reset,” and has returned to the ground state is the photoactive chemical available for another cycle of energy conversion. The process can be repeated over and over again. Since photoactive chemicals are designed by nature to convert these energies, they are quite robust and are able to repeat this process indefinitely under the correct environmental circumstances.

In this respect, before explaining at least one embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a diagram showing the physical relationships between the major components of the invention.

FIG. 2 shows the major components of the invention supported in a structural housing framework.

FIG. 3 is a top plan view of the light interrupter.

FIG. 4 is a diagram of the light resolving mechanism and its relationship to individual photoactive chemicals.

FIG. 5 shows a portion of the segment of the photoactive chemicals.

FIGS. 6A, B, and C are diagrams depicting electrode configurations.

FIG. 7 is a diagram showing the chemical and electrical components of the invention with the controller.

### DESCRIPTION OF THE PREFERRED EMBODIMENT

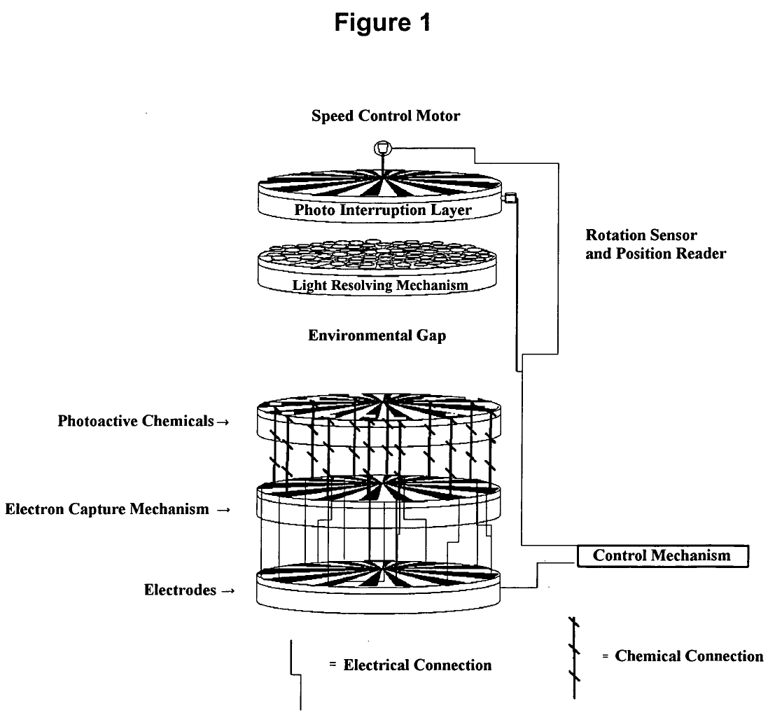

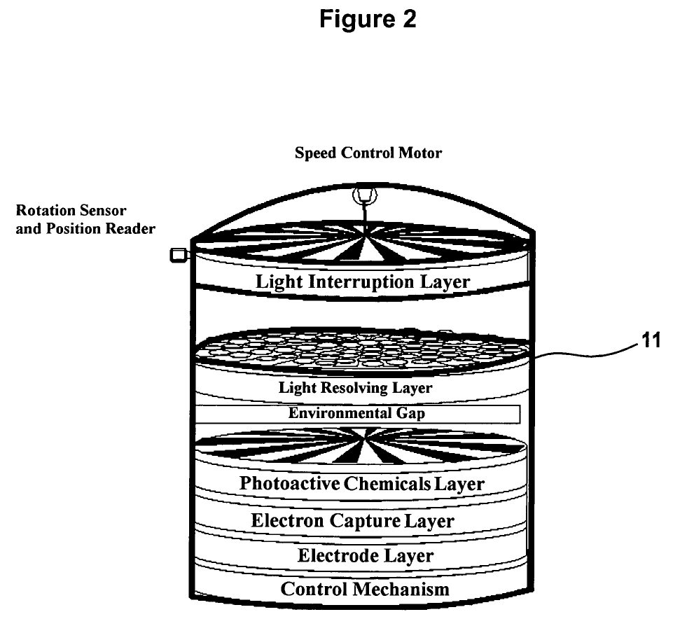

FIG. 1 depicts the electrical and chemical connections between the major components of the invention as described above. As further described above, the present photovoltaic device is regulated by a control mechanism to maximize its current output depending upon the changing intensity of incident sunlight striking the device. FIG. 2 shows the components of the invention as they may be supported by a housing framework 11 in superposition in layers to receive and process incident sunlight.

The invention can be built using known construction methods. The housing can be made of many different materials, although aluminum is employed in this example. An aluminum base and walls provide the support structure for the photoactive membrane and the light resolving mechanism. This housing framework provides physical support and electrical grounding, and has enough height to provide separation from the light resolving mechanism and the photosensitive membrane such that the resolved light targets specific photoactive chemicals. The height can be adjusted based on the resolving power of the resolving mechanism. The support structure can be provided by aluminum formed sections. The base should be of the same size and shape as the photoactive membrane. The base also provides for the electrodes to be connected to the control mechanism. This housing framework also provides a central axis around which the light interrupting mechanism can rotate. This housing ensures that the sector shapes of the photoactive membrane and the light interrupting device are properly aligned.

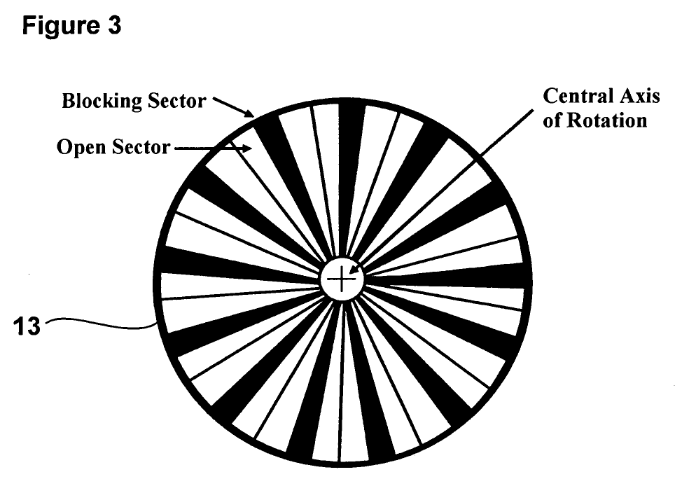

Referring now to FIG. 3, the light interrupter of this embodiment is a rotating disk 13 with slots or some other alternating, light-blocking physical mechanism which can provide a physical interruption of the direct sunlight. It functions much like a rotary shutter, providing light to pass through intermittently. The device is subdivided into sectors, and the number and ratio of sectors are determined by various factors, including efficiency. The sectors of the light interrupting device should closely correspond by sector to the dimensions of the overall device. The ratio of open and closed sectors may vary. The open sectors will simply allow light to pass through unobstructed, and the closed sectors will not allow light to pass through. This portion of the device can be made from any material which can block light or allow light to pass when removed from the light path. The interrupter's rate of rotation should be regulated by a controller as described below with the polarity change of the electrodes so that the photoactive chemicals have sufficient time to return to their uncharged, or ground, state.

The shape of the sector should match the shape of the photoactive chemical sectors, the electron capture sectors and the electrode sectors. If necessary, these sectors should all need to be aligned so that when the light blocking sector is positioned over the photoactive chemicals the polarity of the electrodes can be reversed and the photoactive chemicals can be reset. When the open sectors of the light interrupter are positioned over the photoactive chemicals, the sunlight will pass through the open sectors, through the light resolving mechanism and will strike the photoactive chemicals, energizing them. By having a rotating disk with wedge-shaped sectors of the same size as the photoactive chemical sectors, an entire sector may be covered sufficiently for the photoactive chemicals to return to an uncharged, or ground, state. This feature is optional, depending on the selected photoactive chemicals and the desired efficiencies. In the drawings, the sectors are represented by elongated long triangles radiating out from the center of the device. As the interrupter rotates, the open and blocking sectors move and/or rotate, while all of the lower levels' sectors are stationary. This creates a constantly changing environment for the photoactive chemicals.

The rate of the interrupter's rotation is also proportional to the intensity of the sunlight: The more intense the sunlight, the faster the photosensitive chemicals will become activated. Once they are activated they cannot absorb any more sunlight and need to be discharged. Given that the intensity of sunlight can vary from 25 to 1000 Watts per square meter, the rates of change will need to vary by several orders of magnitude from hundreds of cycles per second to millions of cycles per second.

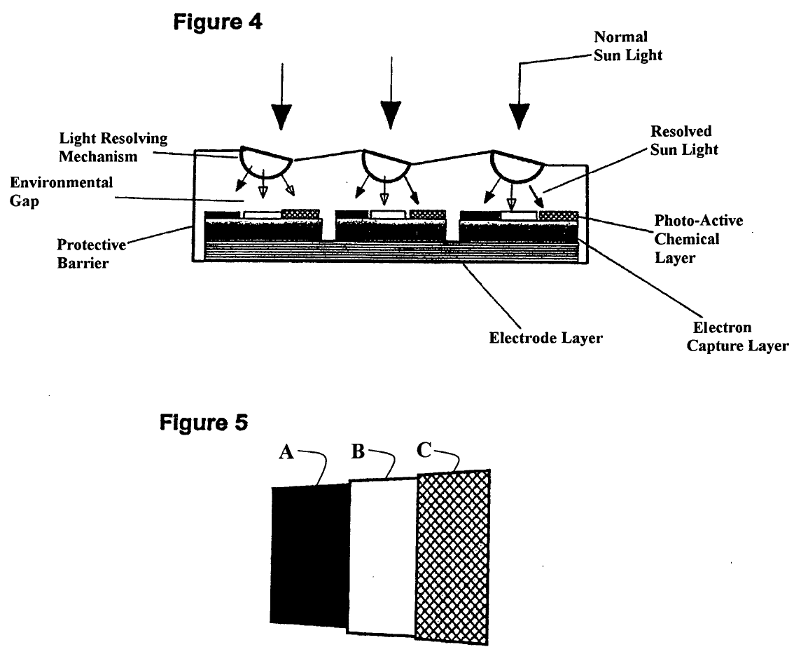

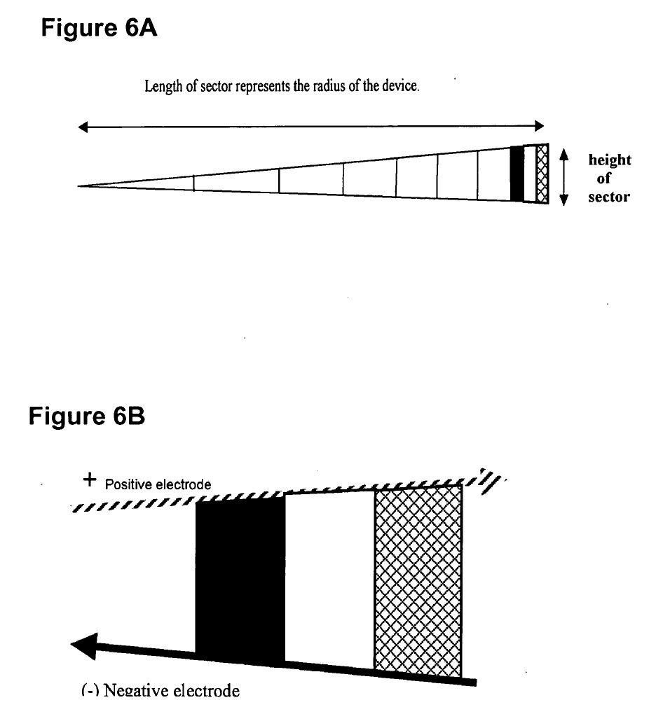

Referring now to FIG. 4, and proceeding in the order in which incident sunlight is processed by the device, the preferred embodiment next includes a light resolving mechanism that breaks the homogeneous light into the constituent wavelength regions, from infrared, through visible light, to ultraviolet. By separating the sunlight into wavelength regions from infrared, through the visible wavelengths to the ultraviolet wavelengths, the device can focus each wavelength region onto those photoactive chemicals which can best utilize that specific wavelength region. As shown in FIG. 5, for example, trans-retinal has a wavelength maximum between 500 and 650 nanometers (nm), which is the yellow to green region of visible light. At this wavelength region, the trans-retinal will absorb a very high percentage of this light and convert the sunlight energy into chemical energy in the form of excited state electrons. Other photoactive chemical classes, such as alpha-carotene and beta-carotene (which are longer form of trans-retinal), absorb light in the UV-A and UV-B regions, which are between 200 and 400 nm. These wavelength regions are lower intensity but have higher energy.

Once the housing base and walls are prepared, the light resolving mechanism(s) can be installed such that they will provide a top or lid of the housing. The light resolving mechanism can be made of many different materials. The walls should be strong and high enough such that the light resolving mechanism is supported. The housing should be electrically insulating, high enough to focus the resolved light onto the desired photoactive chemicals, and capable of providing a central axis around which the light interrupting device rotates.

The resolving mechanism has three functions. The primary function of the resolving mechanism is to separate the light into its constituent wavelengths, as explained above. The second function of the resolving mechanism is to remove harmful light from certain photoactive chemicals. For example, some photoactive chemicals that function well at green light may be harmed by ultraviolet light. This resolving function not only focuses a specific wavelength region of light onto the specific photoactive chemicals that can best utilize that given wavelength region, but it also removes the harmful light from those chemicals that may be damaged by different types of solar energy. This portion of the device is optional depending on types of photoactive chemicals and the efficiencies desired. The light resolving mechanism can be any material or design that can resolve sunlight into its constituent wavelengths examples are glass prisms and prismatic film. This portion of the device is designed to target certain light to certain photoactive chemicals that can utilize a given wavelength region, i.e. ultraviolet, visible light or infrared light. The most obvious mechanism would be a prism of a size and shape such that the output of the light resolving mechanism would be matched to target the sectors of the photoactive chemicals, i.e., where the red light was targeted to those photoactive chemicals which absorb red light, and green light is targeted to those photoactive chemicals which absorb green light. This portion of the device can be rigid and thereby provide physical protection to the photoactive chemicals. The distance from the photoactive chemicals may be highly variable depending on the resolving power of the material used to resolve the light.

The third function of the resolving mechanism is to provide a physical protective barrier between the photoactive chemicals and harmful aspects of the environment such as dirt, wind, rain, and hail. All of these environmental stresses will harm the photoactive chemicals. Much like the human eye, the resolving mechanism has both resolving and protective functions. The protective barrier also allows for the creation of an environmental gap. This gap can be used as a space to create an environment which can promote efficiency and/or stability of the conductive polymers.

Once the housing and the light resolving mechanism are installed, the light interrupting device can be installed if needed. A circular aluminum frame matches the size and shape of the housing, with some sectors removed such that when the removed sectors are positioned above the photoactive materials they expose the photoactive membrane to sunlight. When the un-removed sectors of the aluminum light-interrupting device are positioned above the photoactive chemicals, they are protected or shadowed from the sun. The outer diameter of the aluminum light-interrupting device is contiguous such that all sectors are connected by a circular portion that maintains the shape of the light interrupting device while it is rotating. The speed control device drives the outer portion of the light interrupting device, and the center point of the light interrupting device fits over an axis point around which the light interrupting device can rotate.

With further reference to FIGS. 1 and 2, there is next included a gap or space between the photoactive chemicals and the light resolving mechanism. This environmental gap is optional and is not necessarily required, however this gap offers the ability to change the environment of the photoactive chemicals. This environment may be a vacuum or may be filled with an inert gas or solvent. The gap may offer an opportunity to change the working environment to one which maximizes the photoactivity of the photoactive chemicals, or to provide an environment which maximizes efficiencies and/or stability.

A key aspect of the invention is the concurrent use of selective, wavelength-sensitive photoactive chemicals. As shown in FIG. 5, the light-receiving photochemicals are arranged in segments corresponding to the sectors of light cast through the light resolving mechanism by the interrupter. Each segment is broken into regions corresponding to the associated wavelength, from the infrared through the visible to the ultraviolet. These photoactive chemicals may be any organic or inorganic material which reversibly absorbs light. Trans-retinal is made up of a conjugated double bond system, meaning that there are alternating double and single carbon-carbon bonds. This conjugation is an important aspect such that when retinal absorbs light it transfers the light energy into chemical energy by elevating certain double bonds to what is referred to as “excited” bonds. These excited bonds share electrons in what is called a “Pi cloud.” The excited electrons in the Pi cloud can go from a Pi cloud to an excited Pi cloud, usually written as Pi→Pi*. It is this Pi* which is the conversion process from solar energy to chemical energy. The excited state occurs very fast and is very short lived; however, it is during this excited state that the electrons are loose and are available to move from one Pi cloud to another. At this point, the loose electrons usually result in a isomerization of the chemical from trans-retinal to cis-retinal, and the electrons are kept within the chemical.

The molecular structures of some photoactive chemicals suitable for use with the invention are as follows:

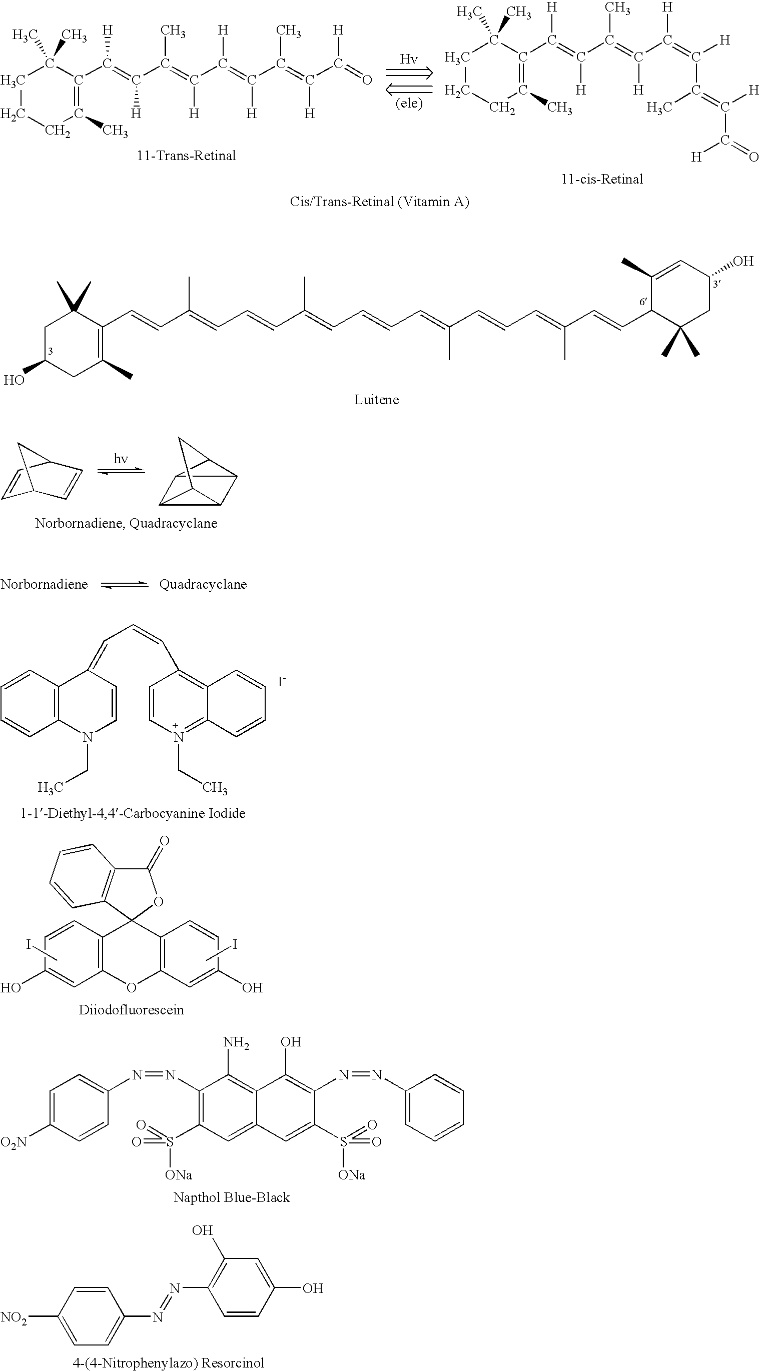

To prepare the photoactive membrane, one should start with a conductive polymer matrix. The polymer matrix can be of many different types, although only one method is used as an example here: Polyacetylene can be made according to the Shirakawa method using a Ziegler-Natta catalyst. This will produce a conjugated polymer matrix. The polymer can be doped many different ways, although only one method is used as an example here: Polyacetylene can be made conductive via doping with various materials such as iodine or bromine. This will produce a conductive conjugated polymer matrix with a conductive range between 1 and 1000 ohms/cmsq.

Electrodes can be applied to the conductive polymer in many different ways. As but one example, conductive paint (Electro Day 502) can be sprayed or silk screened onto the back side of the polyacetylene in almost any shape. However, these shapes must be coordinated to the segment and sector design of the photoactive chemicals and the light interrupting portions of the device.

The chemical linkage to photosensitive chemicals is an important aspect of the invention. If different photoactive chemicals are being used then they must be applied in the segment configuration that matches the light resolving mechanism. The photoactive chemicals can be applied to the conductive polymer in many different ways. As one example, trans-retinal can be linked to the conductive matrix using a Schiff-base catalyzed reaction mechanism. This method enables the top portion of the device to respond to the specific wavelengths of light (500-650 nm).

Once the photoactive chemicals are applied to the front portion of the conductive matrix, the membrane is ready to be mounted into the housing. At this point the membrane must be aligned to the electrical connections of the housing and aligned with the light resolving mechanism of the housing.

The photoactive chemicals are organized into sectors and segments as shown in FIG. 5. The sectors correspond to the same size and shape of the sectors of the light interrupting mechanism. These sectors are designed so that all varieties of the photoactive chemicals can be reset at the same time, when the blocking sector of the light interrupting mechanism is creating a shadow on the photoactive chemicals. Segments are subdivisions of the sectors, each receiving a different wavelength range of light. These segments are aligned with the light resolving mechanism, such that when the light resolving mechanism separates the infrared light it will be targeted to the segment which has photoactive chemicals that are most sensitive to infrared light. The visible light will be targeted to those segments which have photoactive chemicals that are most sensitive to visible light. The ultraviolet light will be targeted to those segments which have chemicals that are most sensitive to ultraviolet light. The photovoltaic device of my invention can have as many segments as there are different photoactive chemicals with specific wavelengths.

With further reference to FIG. 1, the preferred embodiment next includes an electron capture mechanism made of conductive polymers, semi-conductive polymers, a variety of graphite based materials, metal films or silicone-based materials. As explained above, the device is broken into sectors and segments or subdivisions of the sectors, each sector being closely aligned with the light interrupting device. However the segments' size and shape will be coordinated with the light resolving mechanism. Each segment has a region such that infrared light is targeted onto infrared-active chemicals and visible light is targeted onto visible-light-active chemicals, and ultraviolet light is targeted onto ultraviolet-active chemicals. As shown in FIG. 5, each segment will be further broken into areas A, B and C so that each area can be resolved into several different photo-chemical regions of approximately equal area.

It is the principal function of the electron capturing matrix to interface with the photoactive chemicals in such a way that they are connected to the electron cloud of the photoactive chemicals. It is this intimate chemical connection to electron cloud that enables this technology to function with maximum efficiency. The connection between the photoactive chemicals and the electron capture mechanism allows the charge to move electrons from the photoactive chemical into the electron capture mechanism. Conductive polymers are the best choices to become directly connected to the electron cloud of the photoactive chemical because most conductive polymers have their own conjugated chemical double-bond system. One example of a conjugated semi-conductive polymer is polythiophene. Polythiophene is a series of 5-membered rings with an alternating series of single and double carbon-carbon bonds.

Polythiophene is conductive because the electrons in the clouds are free to move from one ring to another. By combining the photoactive chemicals (trans-retinal) to the polythiophene through a carbon-carbon double bond, the chemical conjugation is maintained and electrons within the trans-retinal can move back and forth between the conductive polymer matrix and the photoactive chemical.

### Norbomadiene Chemically Integrated into Poly Pyrole

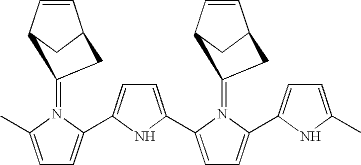

### Polythiophene Chemically Integrated to 4-(4-Nitophenylazo) Resorcinol

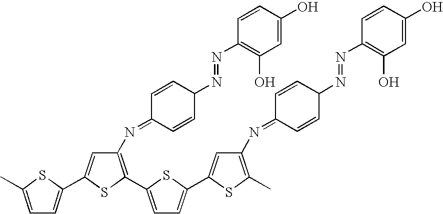

### Trans-Retinal Chemically Integrated into Polyanthrecene

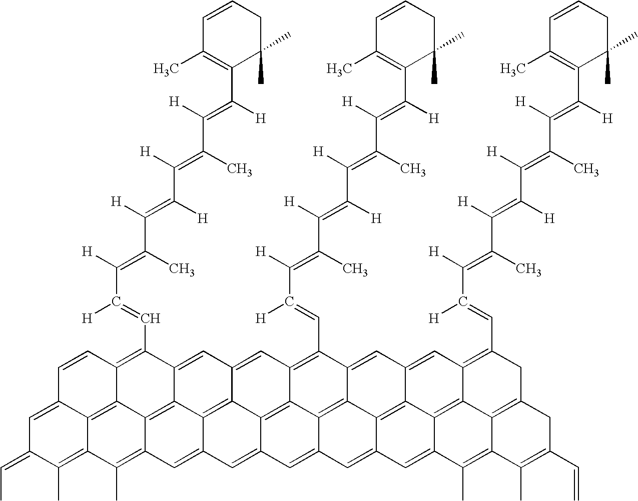

### Tetrathiofluvane

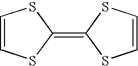

### Antherecene

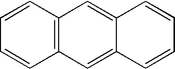

### Poly(p-phenylene vinylene

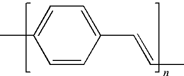

### Graphite

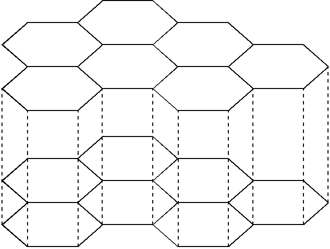

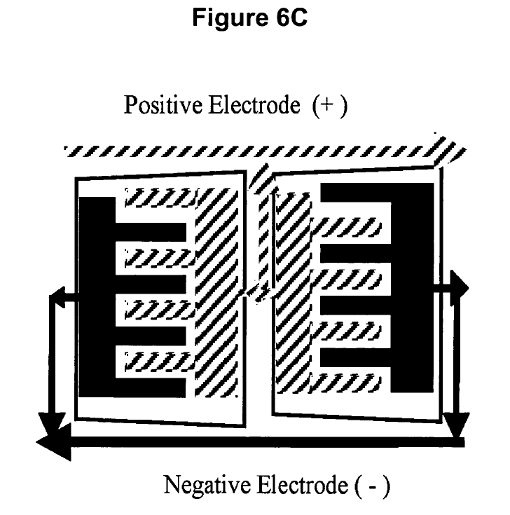

Referring now to FIGS. 6A, 6B and 6C, next in the process sequence, and an important feature of the preferred embodiment, are the electrodes. The electrodes and the electrode configuration are designed to remove the charge from the electron capture mechanism once it has been taken from the photoactive chemicals. Once the charge has been removed from the electron capture mechanism into the electrodes, it can be channeled into a standard electrical storage device, such as a battery. The electrodes may need to reverse polarity or be tied to ground so that the photoactive chemicals can relax back to the ground state.

The electrode configuration should correspond to the sector configuration of the light interrupting mechanism and the segment configuration of the photoactive chemicals for the highest efficiency. This structure is needed to coordinate the polarity change of the electrodes with the light interrupting mechanism's blocking function. This structure is also needed to take the charge away from each of the different segments of the photoactive chemicals shown in FIG. 5.

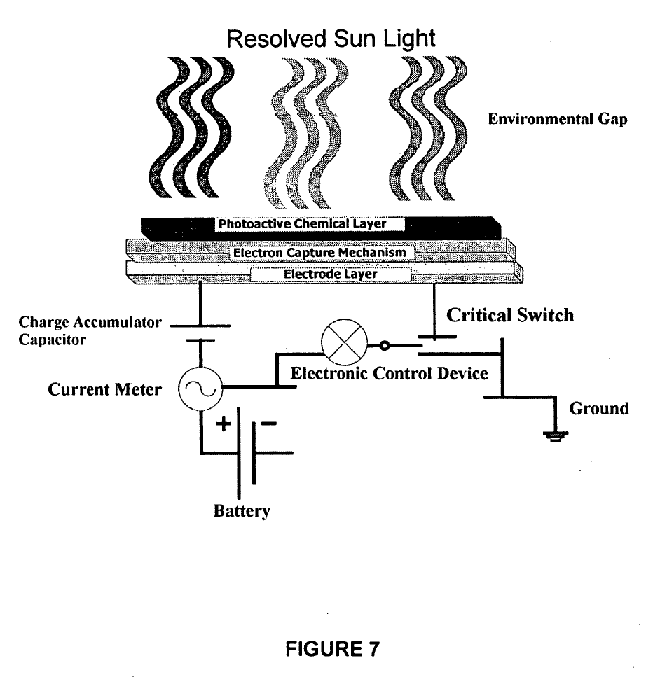

The operation of the components described above is regulated by an electronic control mechanism, as diagrammatically shown in FIG. 7. The mechanism in this embodiment is a microprocessor-based feedback system to regulate the polarity of the electrodes and, if needed, the light interruption device. The coordination of the change in polarity is driven by the output of the device. The control mechanism is designed to deliver electrical current to a storage system, such as a battery, and to allow just enough time for the photoactive chemicals to return to the ground state before exposing them to light once again. The measurement of current and/or voltage is connected to the critical switch that is responsible for changing the polarity and/or grounding the electrodes. When the electrodes are in one state the current will flow into the charge accumulator, possibly a capacitor, through a meter and to the storage device. When the control mechanism switches the polarity or ties the system to ground, the electrodes will allow the electron capture mechanism to return the photoactive chemicals to ground state. The cycle rate is regulated to maximize current flow. If increased cycle rates increase current flow then they will continue to increase current. Once the current has been maximized, this rate will be maintained until the current drops. As the light intensity changes, the cycle rates will change to maximize current flow.

The control mechanism is connected once the housing, light resolving mechanism and light interrupting device are installed as shown in FIGS. 1 and 2. The control mechanism can start to control the power flow. The control module may be made of many different logic systems, such as, for example, a logic control system which monitors the location of the sectors and coordinates the connections of the photoactive membrane with either a battery or a grounding leg. The logic control system is tied to a feedback loop that is driven by current. This feedback system optimizes current flow and speeds up the light interrupting device and the cycle rate between the battery and ground, such that as current drops the cycle rate drops until the current is maximized. Conversely, the cycle rate increases as the current increases, until it reaches the point at which increasing cycle rate causes a drop in current. This system enables the device to work at the maximum current flow as the overall intensity of sunlight changes.

All of these features of this invention, are coordinated by the control mechanism, and result in an efficient conversion of solar energy into electrical energy. Much like a car, all of the pieces must work together to create a functioning mechanical device. This technology resolves and target specific wavelengths of light onto specific photoactive chemicals to convert sunlight to an electrical charge on the photoactive chemical, which will be shared by the electron capture system. The electron capture mechanism transfers the electrons the electrodes and into an external storage system, such as a battery. The system is able to repeat this cycle thousands or millions of times each second, depending on the intensity of the sunlight. By measuring the output and coordinating the electrode polarity with the light blocking mechanism, a suitable environment is created for the utilization of several different photoactive chemicals. By controlling the cycle rate, this technology maximizes efficiency of the conversion of solar energy into electrical energy, and thus the objects of the invention are achieved.

The foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention. It should be understood that the methodology described above is representative only of one embodiment of the invention. There may be other suitable methods which will produce an equivalent material with slightly different functional properties.

What is claimed as being new and desired to be protected by Letters Patent of the United States is as follows:

1. A photovoltaic device for converting solar energy into electricity, comprising:
a housing framework;
a plurality of different target photoactive chemicals, each supported on said framework and positioned in separate areas to receive a different wavelength of light energy; and
a light resolver affixed to said framework and positioned to receive homogenous sunlight, said resolver breaking said sunlight into constituent wavelength regions and directing each of said regions to one of said plurality of different target photoactive chemicals.

2. The photovoltaic device of claim 1 further including an electron capture mechanism comprising a matrix interfacing with an electron cloud of the photo-active chemicals whereby a charge moves electrons from the photoactive chemical into the electron capture mechanism.

3. The photovoltaic device of claim 1 further including a light interrupter affixed to said framework adapted to cycle between open and closed positions, intermittently blocking and then permitting the passage of incident sunlight to said light resolver.

4. The photovoltaic device of claim 1 wherein said resolver and said photoactive chemicals are supported on said framework being separated by a gap between them.

5. The photovoltaic device of claim 3 further including more than one electrode electrically connected to said electron capture mechanism for removing a charge therefrom.

6. The photovoltaic device of claim 3 further including an electronic controller electrically connected to said electrodes and operative to reverse their polarity in response to an electrical current output thereof.

7. The photovoltaic device of claim 6 further including an electronic controller electrically connected to said electrodes and operative to ground one of the electrodes in response to an electrical current output thereof.

8. The photovoltaic device of claim 6 further including an electrical storage device connected to said current output.

9. The photovoltaic device of claim 3 including an electronic controller electrically connected to said electrodes and operative to regulate the cycle rate of said light interrupter in response to an electrical current output thereof.

10. The photovoltaic device of claim 3 wherein said light interrupter is a rotary apertured disc.

11. The photovoltaic device of claim 1 wherein each of said plurality of different photo-target chemicals receives a different wavelength of light according to their sensitivity to the light wavelength received.

12. The photovoltaic device of claim 6 wherein said photoactive chemicals undergo reversible photoactivity.

13. The photovoltaic device of claim 2 in which said electron capture mechanism is from the group consisting of conductive polymers, semi-conductive polymers, graphite-based materials, metal films and silicone-based materials.

14. The photovoltaic device of claim 2 wherein said electro-capture mechanism is polythiophene.

15. The photovoltaic device of claim 12 in which the photoactive chemicals include trans-retinal.

16. The photovoltaic device of claim 10 wherein said apertures are bordered along sectors of the disk.

17. The photovoltaic device of claim 16 wherein said photoactive chemicals lie in areas dimensionally corresponding to segments of said disk, said segments being subdivisions of said sectors.

18. The photovoltaic device of claim 4 wherein said gap is a sealed volume occupied by a non-ambient condition.

19. The photovoltaic device of claim 4 wherein said gap is a sealed volume occupied by an inert gas.

20. The photovoltaic device of claim 2 wherein said electron capture matrix is from the group consisting of conductive or semiconductive polymers, a metal film and polythiophene. composed of conductive or semiconductive polymers.
